(19) United States
(12) Patent Application Publication
(10) Pub. No.: US 2024/0102703 A1
(43) Pub. Date: Mar. 28, 2024

(54) PELTIER BASED ACTIVE COOLING FOR NOISELESS SYSTEMS WITH EFFICIENT POWER AND IMPROVED PERFORMANCE

(71) Applicant: Intel Corporation, Santa Clara, CA (US)

(72) Inventors: Sreejith Satheesakurup, Cherthala (IN); Rekha Bhagat, Orissa (IN); Shailendra Singh Chauhan, Bengaluru (IN)

(21) Appl. No.: 18/163,081

(22) Filed: Feb. 1, 2023

(30) Foreign Application Priority Data
Sep. 27, 2022 (IN) 202241055273

(51) Int. Cl. F25B 21/02; G06F 1/20; G06F 1/3296; H01L 23/38

(52) U.S. Cl. CPC F25B 21/02; G06F 1/206; G06F 1/3296; H01L 23/38; F25B 2321/0212

(57) ABSTRACT

Systems, apparatuses and methods may provide for technology that includes a Peltier module and a subsystem thermally coupled and electrically coupled to the Peltier module, the subsystem to monitor an operational state of the subsystem, place the Peltier module in a first power mode if the operational state indicates that a demand spike exists with respect to the subsystem, and place the Peltier module in a second power mode if the operational state indicates that the demand spike does not exist with respect to the subsystem, wherein the second power mode is associated with a lower level of system power consumption than the first power mode.

### CROSS-REFERENCE TO RELATED APPLICATIONS

This application claims the benefit of priority to India Provisional Patent Application No. 202241055273, filed Sep. 27, 2022.

### TECHNICAL FIELD

Embodiments generally relate to active cooling systems. More particularly, embodiments relate to Peltier based active cooling for noiseless systems with efficient power and improved performance.

### BACKGROUND

Notebook computers typically use a wireless wide area network (WWAN) module to conduct wireless communications with other devices. Modern usage models may involve the user downloading a movie via the WWAN module prior to boarding a flight or experiencing poor signal strength in the WWAN module while traveling on a train and/or lift/elevator. In each of these instances, the demand on the performance of the WWAN module may spike temporarily, which may in turn cause a sudden increase in power consumption and/or heat in the WWAN module. The increased power consumption and/or heat may trigger throttling of the WWAN module, which leads to reduced performance and/or a negative impact on the user experience. While fan based active cooling solutions may partially address overheating concerns, these solutions may be problematic in terms of reliability (e.g., dust), acoustics (e.g., noise generation) and/or size (e.g., due to “Z-height” form factor restrictions).

### BRIEF DESCRIPTION OF THE DRAWINGS

The various advantages of the embodiments will become apparent to one skilled in the art by reading the following specification and appended claims, and by referencing the following drawings, in which:

FIG. 1 is a plan view of an example of a mobile system including a subsystem according to an embodiment;

FIG. 2 is a side view of an example of a Peltier module according to an embodiment;

FIG. 3A is a plan view of an example of a subsystem including an M.2 form factor and a Peltier module according to an embodiment;

FIG. 3B is a side view of an example of the subsystem of FIG. 3A;

FIG. 4 is a block diagram of an example of a subsystem and a Peltier module according to an embodiment;

FIG. 5 is a flowchart of an example of a method of operating a subsystem according to an embodiment;

FIG. 6 is a more detailed flowchart of an example of a method of operating a subsystem according to an embodiment; and

FIG. 7 is an illustration of an example of a semiconductor package apparatus according to an embodiment.

### DETAILED DESCRIPTION OF EMBODIMENTS

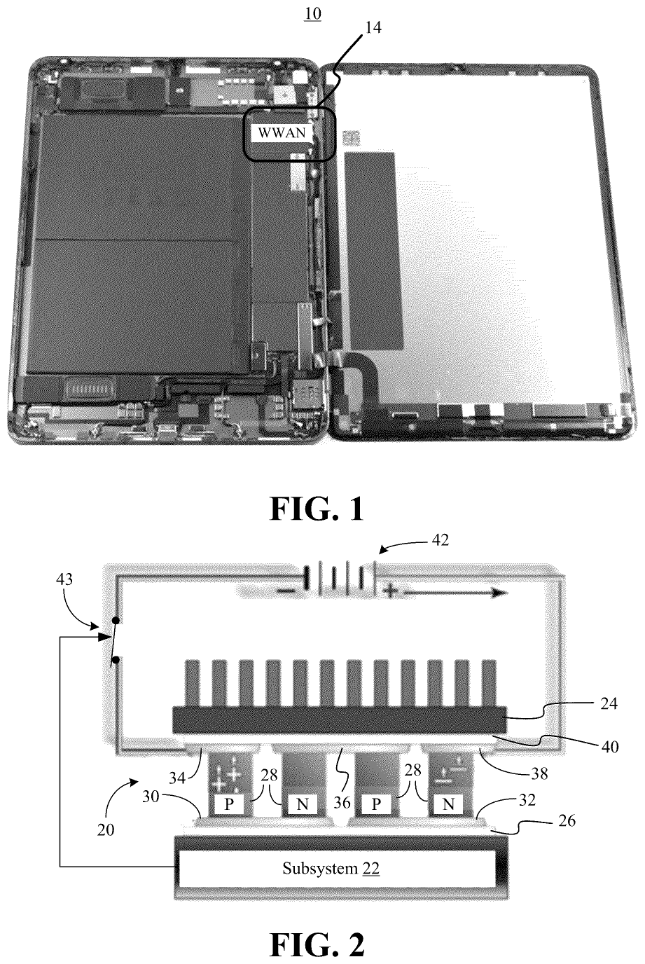

FIG. 1 shows a partially disassembled mobile system 10 (e.g., tablet computer) including a subsystem 14 such as, for example, a WWAN module (e.g., radio chip supporting wireless communications), a solid state drive (SSD, e.g., supporting data storage), and so forth. During operation, a user of the mobile system 10 may request that the subsystem 14 download a movie (e.g., bulk data download prior to boarding a flight) and/or operate the subsystem 14 in an environment having a poor wireless signal (e.g., reduced wireless signal strength while traveling on a train, lift, elevator, etc.). In such a case, a demand spike (e.g., temporary increase/peak in performance demand) might occur, which may in turn cause a sudden increase in power consumption and/or heat in the subsystem 14. Moreover, the mobile system 10 may have a limited Z-height (e.g., device thickness) constraint that prevents a fan based cooling system from being used.

As will be discussed in greater detail, technology described herein thermally and electrically couples a Peltier module (not shown, active cooling solution) to the subsystem 14 and uses the subsystem 14 to control the amount of system power supplied to the Peltier module. The Peltier module therefore mitigates thermal issues and improves the performance of the subsystem 14 without compromising the performance of the overall mobile system 10.

Turning now to FIG. 2, a Peltier module 20 is shown in which a heat absorption side of the Peltier module 20 is thermally coupled to a subsystem 22 (e.g., WWAN module, SSD) and a heat dissipation side of the Peltier module 20 is thermally coupled to a heat sink 24. More particularly, a first ceramic plate 26 is thermally coupled to the subsystem 22. Additionally, a plurality of thermoelectric (TE) elements 28 (N-type and P-type semiconductor pellets) are thermally and electrically coupled to the first ceramic plate 26 via electrical interconnects 30, 32. In an embodiment, the thermoelectric elements 28 are thermally coupled to the heat sink 24 via electrical interconnects 34, 36, 38 and a second ceramic plate 40. In the illustrated example, the thermoelectric elements 28 are also coupled to a direct current (DC) power source 42 via the electrical interconnects 34, 36, 38.

During operation, the first ceramic plate 26 absorbs heat from the subsystem 22 (e.g., becoming cooler) and the second ceramic plate 40 dissipates heat (e.g., becoming hotter) when a current is passed through the thermoelectric elements 28. The amount of heat to be transferred through the Peltier module 20 from the cold side to the hot side may be denoted as Q (e.g., specified in Watts (W)). The Peltier module 20 is therefore a current-driven device. In one example, target operating parameters are most conveniently achieved by driving the Peltier module 20 with a controlled current source and allowing the current source to provide the required load voltage (e.g., the voltage compliance of the current source). A notebook metal case may be readily substituted for the heat sink 24, which distributes thermal energy from the hot side of the Peltier module 20. As will be discussed in greater detail, the subsystem 22 may control the amount of current transferred from the DC power source 42 to the Peltier module 20 via a switch 43 or other suitable device.

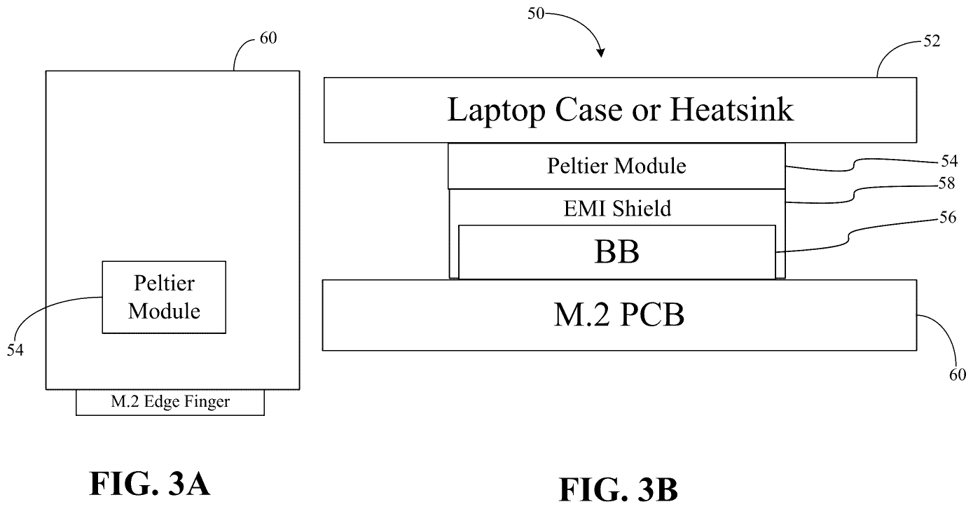

FIGS. 3A and 3B show a subsystem 50 that includes a thermal dissipator 52 (e.g., notebook/laptop case, heat sink) mounted to a Peltier module 54, wherein the Peltier module 54 provides active cooling for a baseboard (BB) processor 56 (e.g., containing a power amplifier that generates a considerable amount of heat during operation). The baseboard processor 56, which may be coupled to the Peltier module 54 via an electromagnetic interference (EMI) shield 58 is mounted on a printed circuit board (PCB, e.g., expansion card) 60 having a form factor that is compliant with M.2 (e.g., Peripheral Component Interconnect/PCI Express M.2 Specification, Revision 4.0, Version 1.0, Nov. 5, 2020).

In this regard, the maximum M.2 power available may be less than that required to support a wireless (e.g., Sub-6 GHz fifth generation/5G, millimeterWave (mmWave)) application. Accordingly, the technology described herein enables the Peltier module 54 to operate on system power rather than the power supplied to the subsystem 50 (e.g., through M.2 edge finger contacts). Moreover, embodiments use an intelligent approach to enable the Peltier module 54 only when the baseboard processor 56 crosses a critical junction temperature or when a system application causes the subsystem 50 to draw more power than the maximum M.2 power capability. Such an approach mitigates thermal issues in the subsystem 50 and improves the performance of the subsystem 50 in usage models having relatively high bandwidth and resource demands.

Indeed, existing thermal solutions such as heat spreaders, EMI shields, heat sinks, and fan based solutions cannot be scaled easily to applications having Sub-6 GHz 5G and mmWave requirements. The technology described herein makes use of the Peltier module 54 to cool the subsystem 50 in an enhanced way to overcome efficiency issues by operating the Peltier module 54 dynamically. The illustrated implementation can also be used in systems having tight Z-height restrictions (e.g., thin and light clamshell-type systems).

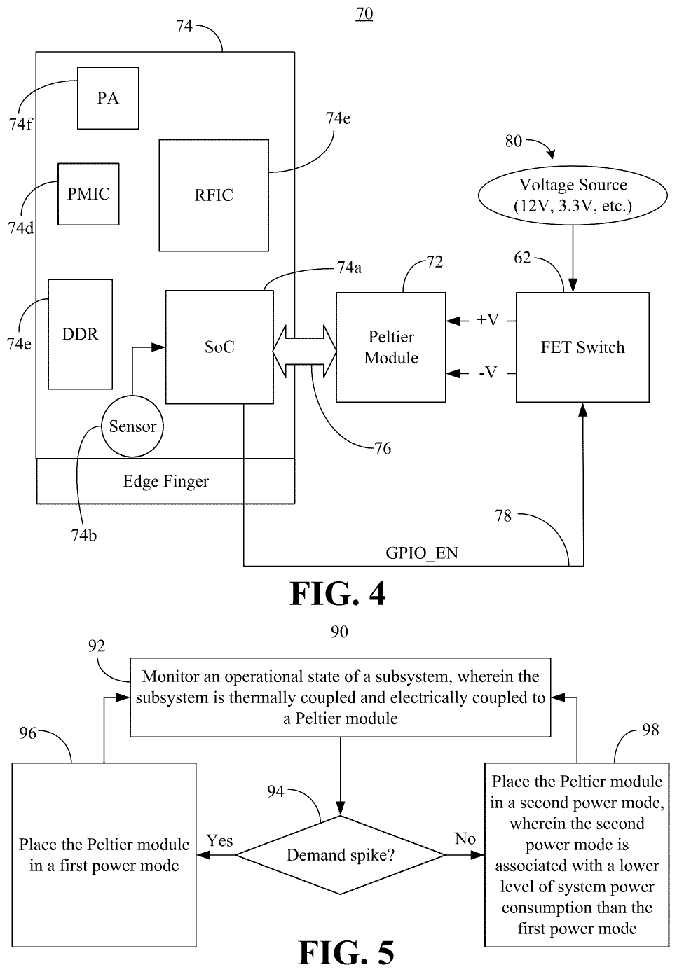

FIG. 4 shows a mobile system 70 that includes a Peltier module 72 and a subsystem 74 (74a-74f) that is coupled to the Peltier module 72 via a thermal interface 76 (e.g., ceramic substrates) and an electrical interface 78 (e.g., general purpose input output/GPIO enable line, electrical interconnects). The illustrated Peltier module 72 includes a system on chip (SoC, e.g., including a baseboard processor, envelope tracker, etc.) 74a, a thermal sensor 74b (e.g., thermistor), a memory 74c (e.g., dual data rate/DDR dynamic random access memory/DRAM), a power management integrated circuit (PMIC) 74d, a radio frequency integrated circuit (RFIC, e.g., including a radio frequency/RF transceiver and front-end blocks to perform RF transmission and reception) 74e, and a power amplifier 74f The subsystem 74 may also include other components such as, for example, a global navigation satellite system (GNSS) receiver chip, depending on the circumstances.

In general, the Peltier module 72 may be a relatively inefficient device. For example, for ˜2 W of operating power, the Peltier module 72 may draw 4.5 W of input power. Accordingly, embodiments keep the Peltier module 72 in a dynamically/selectively powered ON state instead of an always ON state. In one Hyper UE mode (HPUE) use case where the SoC 74a and the power amplifier 74f operate at maximum power levels and highest operating temperatures, more heat is dissipated, which leads to deterioration of the wireless link quality and throughput performance. During that time, the Peltier module 72 can be dynamically turned on and pump out the excess heat from the SoC 74a (e.g., enhancing performance).

As already discussed, the power from an M.2 form factor is limited (e.g., 8.25 W) and when the mobile system 70 is fully functional, using the M.2 power for the Peltier module 72 might limit the power available for the rest of subsystem 74. Accordingly, embodiments use system power 80 to supply the Peltier module 72. An implementation can be done in such a way that the control for the Peltier module 72 can come from the SoC 74a via the electrical interface 78 and a switch 62 (e.g., field effect transistor/FET). The control can be a simple ON or OFF with the electrical interface 78 to control the power to the Peltier module 72 or pulse width modulation (PWM, e.g., duty cycle increase/decrease) based control to vary the amount of power delivered to the Peltier module 72.

The mobile system 70 is therefore considered performance-enhanced at least to the extent that dynamically raising the system power 80 consumption of the Peltier module 72 when demand spikes are present enables the subsystem 74 to cool down, avoid throttling and operate at higher bandwidth and/or operating frequencies. Additionally, dynamically reducing the system power 80 consumption of the Peltier module 72 when the demand spikes are not present increases the efficiency of the Peltier module 72. Moreover, use of the Peltier module 72 eliminates acoustic noise, obviates Z-height considerations, increases reliability and/or lowers costs relative to fan based cooling.

Although primarily described as a mobile system 70, the system 70 may generally be part of any electronic device/platform having computing functionality (e.g., personal digital assistant/PDA, notebook computer, tablet computer, convertible tablet, server), communications functionality (e.g., smart phone), imaging functionality (e.g., camera, camcorder), media playing functionality (e.g., smart television/TV), wearable functionality (e.g., watch, eyewear, headwear, footwear, jewelry), vehicular functionality (e.g., car, truck, motorcycle), robotic functionality (e.g., autonomous robot), Internet of Things (IoT) functionality, etc., or any combination thereof.

FIG. 5 shows a method 90 of operating a subsystem of a mobile system. The method 90 may generally be implemented in a subsystem such as, for example, the subsystem 14 (FIG. 1), the subsystem 22 (FIG. 2), the subsystem 50 (FIG. 3B) and/or the subsystem 74 (FIG. 4), already discussed. More particularly, the method 90 may be implemented in one or more modules as a set of logic instructions stored in a machine- or computer-readable storage medium such as random access memory (RAM), read only memory (ROM), programmable ROM (PROM), firmware, flash memory, etc., in hardware, or any combination thereof. For example, hardware implementations may include configurable logic, fixed-functionality logic, or any combination thereof. Examples of configurable logic (e.g., configurable hardware) include suitably configured programmable logic arrays (PLAs), field programmable gate arrays (FPGAs), complex programmable logic devices (CPLDs), and general purpose microprocessors. Examples of fixed-functionality logic (e.g., fixed-functionality hardware) include suitably configured application specific integrated circuits (ASICs), combinational logic circuits, and sequential logic circuits. The configurable or fixed-functionality logic can be implemented with complementary metal oxide semiconductor (CMOS) logic circuits, transistor-transistor logic (TTL) logic circuits, or other circuits.

The illustrated processing block 92 monitors an operational state of the subsystem, wherein the subsystem is thermally coupled and electrically coupled to a Peltier module. Block 92 may include monitoring a temperature of the subsystem via a sensor such as, for example, the sensor 74b (FIG. 4) and/or a power consumption of the subsystem via a power management controller such as, for example, the PMIC 74d (FIG. 4). Block 94 determines whether the operational state of the subsystem indicates that a demand spike exists with respect to the subsystem. In one example, the demand spike is associated with a bulk data download to the subsystem (e.g., movie download before a flight). In another example, the demand spike is associated with a reduced wireless signal strength in the subsystem (e.g., operation while traveling on a train, lift or elevator).

Thus, block 94 might include determining whether the temperature of the subsystem exceeds a temperature threshold (e.g., critical junction temperature). Block 94 may also involve determining whether the power consumption of the subsystem exceeds a power threshold. If so, block 96 places the Peltier module in a first power mode. Otherwise, block 98 places the Peltier module in a second power mode, wherein the second power mode is associated with a lower level of system power consumption than the first power mode. In one example, block 96 includes enabling (e.g., via a switch) a connection between the system power and the Peltier module and block 98 includes disabling (e.g., via the switch) the connection between the system power and the Peltier module. In another example, block 96 includes increasing (e.g., via a switch) a duty cycle of a connection between the system power and the Peltier module and block 98 includes decreasing (e.g., via the switch) the duty cycle of the connection between the system power and the Peltier module. Additionally, the subsystem may include an M.2 form factor and one or more of an SSD or a radio chip.

The method 90 therefore enhances performance at least to the extent that dynamically raising the system power consumption of the Peltier module when demand spikes are present enables the subsystem to cool down, avoid throttling and operate at higher bandwidth and/or operating frequencies. Additionally, dynamically reducing the system power consumption of the Peltier module when the demand spikes are not present increases the efficiency of the Peltier module. Moreover, use of the Peltier module eliminates acoustic noise, obviates Z-height considerations, increases reliability and/or lowers costs relative to fan based cooling.

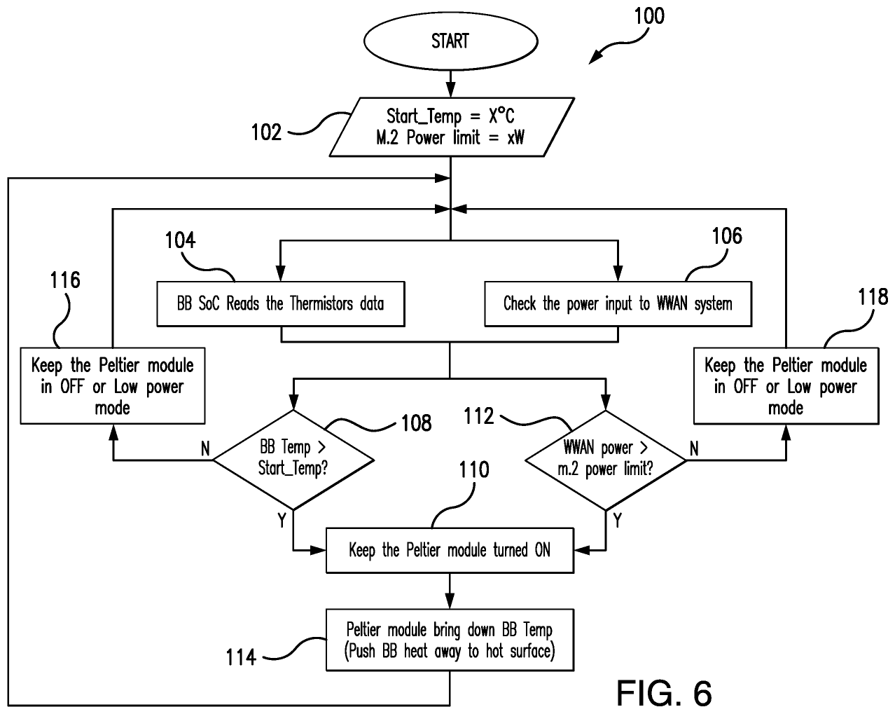

FIG. 6 shows a more detailed method 100 of operating a subsystem of a mobile system. The method 100 may generally be implemented in a subsystem such as, for example, the subsystem 14 (FIG. 1), the subsystem 22 (FIG. 2), the subsystem 50 (FIG. 3B) and/or the subsystem 74 (FIG. 4), already discussed. More particularly, the method 100 may be implemented in one or more modules as a set of logic instructions stored in a machine- or computer-readable storage medium such as RAM, ROM, PROM, firmware, flash memory, etc., in hardware, or any combination thereof. For example, hardware implementations may include configurable logic, fixed-functionality logic, or any combination thereof.

Illustrated processing block 102 sets a start temperature and power consumption limit of the subsystem. In an embodiment, the baseband SoC reads thermistor data at block 104 and block 106 checks the power input to the subsystem. A determination may be made at block 108 as to whether the thermistor temperature exceeds the start temperature. If so, block 110 keeps the Peltier module turned ON. A determination may also be made at block 112 as to whether the power input to the subsystem exceeds the power consumption limit. If so, block 110 keeps the Peltier module turned ON, wherein the Peltier module brings down the temperature of the subsystem at block 114 and the illustrated method 110 repeats.

If it is determined at block 108 that the thermistor temperature does not exceed the start temperature, block 116 keeps the Peltier module turned OFF or in a low power mode (e.g., reduced PWM duty cycle) and the illustrated method 100 repeats. Similarly, if it is determined at block 112 that the power input to the subsystem does not exceed the power consumption limit, block 118 keeps the Peltier module turned OFF or in a low power mode (e.g., reduced PWM duty cycle) and the illustrated method 100 repeats.

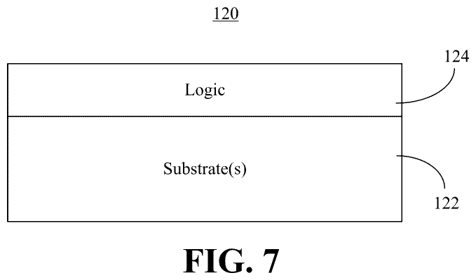

FIG. 7 shows a semiconductor apparatus 120 (e.g., chip and/or package). The semiconductor apparatus 120 may generally be incorporated into or substituted for the subsystem 14 (FIG. 1), the subsystem 22 (FIG. 2), the baseboard processor 56 (FIG. 3B) and/or the SoC 74 (FIG. 4), already discussed. More particularly, the illustrated apparatus 120 includes one or more substrates 122 (e.g., silicon, sapphire, gallium arsenide) and logic 124 (e.g., transistor array and other integrated circuit/IC components) coupled to the substrate(s) 122. In an embodiment, the logic 124 and implements one or more aspects of the method 90 (FIG. 5) and/or the method 100 (FIG. 6), already discussed. Thus, the logic 124 may monitor an operational state of a subsystem including the apparatus 120, wherein the subsystem is to be thermally coupled and electrically coupled to a Peltier module. The logic 124 also places the Peltier module in a first power mode if the operational state indicates that a demand spike exists with respect to the subsystem. In addition, the logic 124 places the Peltier module in a second power mode if the operational state indicates that the demand spike does not exist with respect to the subsystem, wherein the second power mode is associated with a lower level of system power consumption than the first power mode.

The logic 124 may be implemented at least partly in configurable or fixed-functionality hardware. In one example, the logic 124 includes transistor channel regions that are positioned (e.g., embedded) within the substrate(s) 122. Thus, the interface between the logic 124 and the substrate(s) 122 may not be an abrupt junction. The logic 124 may also be considered to include an epitaxial layer that is grown on an initial wafer of the substrate(s) 122.

### Additional Notes and Examples

Example 1 includes a mobile system comprising a Peltier module and a subsystem thermally coupled and electrically coupled to the Peltier module, the subsystem including logic coupled to one or more substrates, wherein the logic is to monitor an operational state of the subsystem, place the Peltier module in a first power mode if the operational state indicates that a demand spike exists with respect to the subsystem, and place the Peltier module in a second power mode if the operational state indicates that the demand spike does not exist with respect to the subsystem, wherein the second power mode is associated with a lower level of system power consumption than the first power mode.

Example 2 includes the mobile system of Example 1, wherein to place the Peltier module in the first power mode, the logic is to enable a connection between the system power and the Peltier module, and wherein to place the Peltier module in the second power mode, the logic is to disable the connection between the system power and the Peltier module.

Example 3 includes the mobile system of Example 1, wherein to place the Peltier module in the first power mode, the logic is to increase a duty cycle of a connection between the system power and the Peltier module, and wherein to place the Peltier module in the second power mode, the logic is to decrease the duty cycle of the connection between the system power and the Peltier module.

Example 4 includes the mobile system of Example 1, wherein the Peltier module is to be placed in the first power mode if a temperature of the subsystem exceeds a temperature threshold, and wherein the Peltier module is to be placed in the second power mode if the temperature of the subsystem does not exceed the temperature threshold.

Example 5 includes the mobile system of Example 1, wherein the Peltier module is to be placed in the first power mode if a power consumption of the subsystem exceeds a power threshold, and wherein the Peltier module is to be placed in the second power mode if the power consumption of the subsystem does not exceed the power threshold.

Example 6 includes the mobile system of any one of Examples 1 to 5, wherein the demand spike is to be associated with a bulk data download to the subsystem.

Example 7 includes the mobile system of any one of Examples 1 to 5, wherein the demand spike is to be associated with a reduced wireless signal strength in the subsystem.

Example 8 includes the mobile system of any one of Examples 1 to 5, wherein the subsystem includes an M.2 form factor and one or more of a solid state drive or a radio chip.

Example 9 includes a subsystem of a mobile system, the subsystem comprising one or more substrates, and logic coupled to the one or more substrates, wherein the logic is implemented at least partly in one or more of configurable or fixed-functionality hardware, the logic to monitor an operational state of the subsystem, wherein the subsystem is to be thermally coupled and electrically coupled to a Peltier module, place the Peltier module in a first power mode if the operational state indicates that a demand spike exists with respect to the subsystem, and place the Peltier module in a second power mode if the operational state indicates that the demand spike does not exist with respect to the subsystem, wherein the second power mode is associated with a lower level of system power consumption than the first power mode.

Example 10 includes the subsystem of Example 9, wherein to place the Peltier module in the first power mode, the logic is to enable a connection between the system power and the Peltier module, and wherein to place the Peltier module in the second power mode, the logic is to disable the connection between the system power and the Peltier module.

Example 11 includes the subsystem of Example 9, wherein to place the Peltier module in the first power mode, the logic is to increase a duty cycle of a connection between the system power and the Peltier module, and wherein to place the Peltier module in the second power mode, the logic is to decrease the duty cycle of the connection between the system power and the Peltier module.

Example 12 includes the subsystem of Example 9, wherein the Peltier module is to be placed in the first power mode if a temperature of the subsystem exceeds a temperature threshold, and wherein the Peltier module is to be placed in the second power mode if the temperature of the subsystem does not exceed the temperature threshold.

Example 13 includes the subsystem of Example 9, wherein the Peltier module is to be placed in the first power mode if a power consumption of the subsystem exceeds a power threshold, and wherein the Peltier module is to be placed in the second power mode if the power consumption of the subsystem does not exceed the power threshold.

Example 14 includes the subsystem of any one of Examples 9 to 13, wherein the demand spike is to be associated with a bulk data download to the subsystem.

Example 15 includes the subsystem of any one of Examples 9 to 13, wherein the demand spike is to be associated with a reduced wireless signal strength in the subsystem.

Example 16 includes the subsystem of any one of Examples 9 to 13, further including an M.2 form factor and one or more of a solid state drive or a radio chip.

Example 17 includes a method of operating a subsystem of a mobile system, the method comprising monitoring an operational state of the subsystem, wherein the subsystem is thermally coupled and electrically coupled to a Peltier module, placing the Peltier module in a first power mode if the operational state indicates that a demand spike exists with respect to the subsystem, and placing the Peltier module in a second power mode if the operational state indicates that the demand spike does not exist with respect to the subsystem, wherein the second power mode is associated with a lower level of system power consumption than the first power mode.

Example 18 includes the method of Example 17, wherein placing the Peltier module in the first power mode includes enabling a connection between the system power and the Peltier module and placing the Peltier module in the second power mode includes disabling the connection between the system power and the Peltier module.

Example 19 includes the method of Example 17, wherein placing the Peltier module in the first power mode includes increasing a duty cycle of a connection between the system power and the Peltier module and placing the Peltier module in the second power mode includes decreasing the duty cycle of the connection between the system power and the Peltier module.

Example 20 includes the method of Example 17, wherein the Peltier module is placed in the first power mode if a temperature of the subsystem exceeds a temperature threshold, and wherein the Peltier module is placed in the second power mode if the temperature of the subsystem does not exceed the temperature threshold.

Example 21 includes the method of Example 17, wherein the Peltier module is placed in the first power mode if a power consumption of the subsystem exceeds a power threshold, and wherein the Peltier module is placed in the second power mode if the power consumption of the subsystem does not exceed the power threshold.

Example 22 includes the method of any one of Examples 17 to 21, wherein the demand spike is associated with a bulk data download to the subsystem.

Example 23 includes the method of any one of Examples 17 to 21, wherein the demand spike is associated with a reduced wireless signal strength in the subsystem.

Example 24 includes the method of any one of Examples 17 to 21, wherein the subsystem includes an M.2 form factor and one or more of a solid state drive or a radio chip.

Example 25 includes an apparatus comprising means for performing the method of any one of Examples 17 to 24.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the computing system within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A mobile system comprising:
a Peltier module; and
a subsystem thermally coupled and electrically coupled to the Peltier module, the subsystem including logic coupled to one or more substrates, wherein the logic is to:
monitor an operational state of the subsystem,
place the Peltier module in a first power mode if the operational state indicates that a demand spike exists with respect to the subsystem, and
place the Peltier module in a second power mode if the operational state indicates that the demand spike does not exist with respect to the subsystem, wherein the second power mode is associated with a lower level of system power consumption than the first power mode.

2. The mobile system of claim 1, wherein to place the Peltier module in the first power mode, the logic is to enable a connection between the system power and the Peltier module, and wherein to place the Peltier module in the second power mode, the logic is to disable the connection between the system power and the Peltier module.

3. The mobile system of claim 1, wherein to place the Peltier module in the first power mode, the logic is to increase a duty cycle of a connection between the system power and the Peltier module, and wherein to place the Peltier module in the second power mode, the logic is to decrease the duty cycle of the connection between the system power and the Peltier module.

4. The mobile system of claim 1, wherein the Peltier module is to be placed in the first power mode if a temperature of the subsystem exceeds a temperature threshold, and wherein the Peltier module is to be placed in the second power mode if the temperature of the subsystem does not exceed the temperature threshold.

5. The mobile system of claim 1, wherein the Peltier module is to be placed in the first power mode if a power consumption of the subsystem exceeds a power threshold, and wherein the Peltier module is to be placed in the second power mode if the power consumption of the subsystem does not exceed the power threshold.

6. The mobile system of claim 1, wherein the demand spike is to be associated with a bulk data download to the subsystem.

7. The mobile system of claim 1, wherein the demand spike is to be associated with a reduced wireless signal strength in the subsystem.

8. The mobile system of claim 1, wherein the subsystem includes an M.2 form factor and one or more of a solid state drive or a radio chip.

9. A subsystem of a mobile system, the subsystem comprising:
one or more substrates; and
logic coupled to the one or more substrates, wherein the logic is implemented at least partly in one or more of configurable or fixed-functionality hardware, the logic to:
monitor an operational state of the subsystem, wherein the subsystem is to be thermally coupled and electrically coupled to a Peltier module;
place the Peltier module in a first power mode if the operational state indicates that a demand spike exists with respect to the subsystem; and
place the Peltier module in a second power mode if the operational state indicates that the demand spike does not exist with respect to the subsystem, wherein the second power mode is associated with a lower level of system power consumption than the first power mode.

10. The subsystem of claim 9, wherein to place the Peltier module in the first power mode, the logic is to enable a connection between the system power and the Peltier module, and wherein to place the Peltier module in the second power mode, the logic is to disable the connection between the system power and the Peltier module.

11. The subsystem of claim 9, wherein to place the Peltier module in the first power mode, the logic is to increase a duty cycle of a connection between the system power and the Peltier module, and wherein to place the Peltier module in the second power mode, the logic is to decrease the duty cycle of the connection between the system power and the Peltier module.

12. The subsystem of claim 9, wherein the Peltier module is to be placed in the first power mode if a temperature of the subsystem exceeds a temperature threshold, and wherein the Peltier module is to be placed in the second power mode if the temperature of the subsystem does not exceed the temperature threshold.

13. The subsystem of claim 9, wherein the Peltier module is to be placed in the first power mode if a power consumption of the subsystem exceeds a power threshold, and wherein the Peltier module is to be placed in the second power mode if the power consumption of the subsystem does not exceed the power threshold.

14. The subsystem of claim 9, wherein the demand spike is to be associated with a bulk data download to the subsystem.

15. The subsystem of claim 9, wherein the demand spike is to be associated with a reduced wireless signal strength in the subsystem.

16. The subsystem of claim 9, further including an M.2 form factor and one or more of a solid state drive or a radio chip.

17. A method of operating a subsystem of a mobile system, the method comprising:
monitoring an operational state of the subsystem, wherein the subsystem is thermally coupled and electrically coupled to a Peltier module;
placing the Peltier module in a first power mode if the operational state indicates that a demand spike exists with respect to the subsystem; and
placing the Peltier module in a second power mode if the operational state indicates that the demand spike does not exist with respect to the subsystem, wherein the second power mode is associated with a lower level of system power consumption than the first power mode.

18. The method of claim 17, wherein placing the Peltier module in the first power mode includes enabling a connection between the system power and the Peltier module and placing the Peltier module in the second power mode includes disabling the connection between the system power and the Peltier module.

19. The method of claim 17, wherein placing the Peltier module in the first power mode includes increasing a duty cycle of a connection between the system power and the Peltier module and placing the Peltier module in the second power mode includes decreasing the duty cycle of the connection between the system power and the Peltier module.

20. The method of claim 17, wherein the Peltier module is placed in the first power mode if a temperature of the subsystem exceeds a temperature threshold, and wherein the Peltier module is placed in the second power mode if the temperature of the subsystem does not exceed the temperature threshold.
